(19) United States
(12) Patent Application Publication
(10) Pub. No.: US 2023/0001369 A1
(43) Pub. Date: Jan. 5, 2023

(54) DOUBLE-TUBE CONNECTION STRUCTURE FOR DETONATION SYNTHESIS, DETONATION SYNTHESIS DEVICE AND APPLICATION THEREOF

(71) Applicant: CHENGDU INFINITE SINGULARITY TECHNOLOGY CO., LTD, Chengdu (CN)

(72) Inventors: Wanjia ZHANG, Chengdu (CN); Ye ZHANG, Chengdu (CN); Lilan FAN, Chengdu (CN); Min ZHANG, Chengdu (CN)

(73) Assignee: CHENGDU INFINITE SINGULARITY TECHNOLOGY CO., LTD, Chengdu (CN)

(21) Appl. No.: 17/866,690

(22) Filed: Jul. 18, 2022

Related U.S. Application Data
(63) Continuation-in-part of application No. PCT/CN2021/072433, filed on Jan. 18, 2021.

(30) Foreign Application Priority Data
Jan. 21, 2020 (CN) 202010071587.0

(51) Int. Cl. B01J 3/08; B01J 3/06

(52) U.S. Cl. CPC B01J 3/08; B01J 3/062; B01J 2203/0655; B01J 2203/061

(57) ABSTRACT

A double-tube connection structure for detonation synthesis, a detonation synthesis device and an application thereof are provided. The double-tube connection structure for detonation synthesis includes a drive tube, a sample tube, fixing components, and end plugs provided at ports of the sample tube. The drive tube is sleeved outside the sample tube, cavities are provided between the drive tube and the sample tube, and between the drive tube and the end plug. The fixing components are provided on two ends of the drive tube and the sample tube. After detonation, a detonation wave is transferred from top to bottom. Under the action of the detonation wave, the drive tube performs convergent sliding motion towards the sample tube, and covers outsides of the sample tube, and the top end plug and the bottom end plug of the sample tube. A detonation synthesis device includes the double-tube connection structure for detonation synthesis.

The present disclosure is a continuation-in-part application of international application PCT/CN2021/072433, which claims priority to Chinese patent application with the filing number 2020100715870 filed on Jan. 21, 2020 with the Chinese Patent Office, and entitled “Detonation Synthesis Device”, the contents of which are incorporated herein by reference in entirety.

### TECHNICAL FIELD

The present disclosure relates to the technical field of new material synthesis, and in particular to a double-tube connection structure for detonation synthesis, a detonation synthesis device, and application thereof.

### BACKGROUND ART

Diamond is a rare multifunctional material, and is a substance with the highest hardness in nature at present, and as the most ideal super-hard material, the diamond has been widely applied in many conventional industrial fields such as machinery, geology, traffics, construction materials, and petroleum, significantly improving the production efficiency, and promoting upgrading and updating of the conventional industries.

Currently, diamond micro-powder and products have been widely applied in the fields such as automobiles, machinery, tools, electronics, integrated circuits, cellphones, aeronautics, aerospace, optical instruments, glass, ceramics, petroleum, geology, sapphires, chips, medical science, and electronic information communications.

The reserves of diamond on the earth are quite rare, and they are hidden in the depths of the earth and not easily mined, and are far from meeting the needs of rapid development of industry and science and technology. Therefore, people spend a lot of manpower and material resources on the scientific researches of synthetic diamond, and have successfully invented two methods for synthesizing diamond. A first method is a static pressing method that uses a high-temperature, high-pressure mechanical equipment to convert graphite into single crystal diamond through phase transformation. At present, this technology has been relatively mature and popular, but this method has large investment in equipment and complex raw materials, and the product particle size is on the order of mm.

A second method is a dynamic pressure synthetic method, in which an impact dynamic high-pressure high-temperature condition is created by the explosion of an explosive, so that graphite is converted into polycrystalline diamond with a particle size on the order of μm in the time scale on the order of μs. The dynamic high-pressure synthetic technology does not require huge and expensive mechanical equipment, and is a new technology for synthesizing new materials. Now only a few companies such as DuPont in the US have fully mastered this technology, and really realize the industrialization.

Compared with monocrystalline diamond, polycrystalline diamond differs not only in crystal structure and particle size, but also quite differs in performances. Polycrystalline diamond has excellent grinding performance, and can be used in the fields of high-grade, high-precision, advanced technologies such as aviation, aerospace, precision ceramics, LED chips, and sapphire substrates. Besides, polycrystalline diamond also has many excellent properties, and has a wide application prospect in national defense and civilian fields.

Diamond and graphite are allotropic crystals of carbon elements, and to artificially synthesize diamond, it would naturally have been readily conceivable to use graphite as a synthetic raw material. A pressure-temperature phase diagram of carbon is a unit complex phase diagram, as shown in FIG. 1. The phase diagram provides temperature and pressure regions in which graphite and diamond are stably present. In a diamond stable region with a relatively high pressure, a graphite-type crystal structure is unstable, and the graphite must be converted into diamond to reduce its own free energy; in contrast, in the graphite stable region with a relatively low pressure, the diamond type polycrystalline structure is unstable, and it should be converted into graphite to reduce its own energy. This multiphase phase diagram of carbon tells people that to synthesize diamond by explosive impact, at least the following requirements must be met:

firstly, a suitable detonation synthesis device must be developed to create a certain high-temperature, high-pressure condition, so that the graphite is converted into diamond;

secondly, the diamond phase existing in high temperature and high pressure should be preserved, when unloaded from transient detonation to normal temperature and normal pressure, preventing graphitization; and

thirdly, as explosion is a process that is quite hard to control, the technical difficult problem of diamond recovery must be solved.

The existing technological difficulties mainly focus on improving the conversion rate and recovery rate of diamond while synthesizing high-purity polycrystalline diamond with dynamic high pressure, and the costs also need to be reduced to the maximum extent to realize industrial production.

### SUMMARY

The technical problem to be solved by the present disclosure is that the existing detonation process of diamond has the problems of a low conversion rate and difficult recovery. The present disclosure provides a double-tube connection structure for detonation synthesis, a detonation synthesis device for solving the problems, and application thereof.

The present disclosure is realized through the following technical solutions.

A double-tube connection structure for detonation synthesis includes a drive tube, a sample tube, and end plugs provided at two ends of the sample tube, wherein the drive tube is sleeved outside the sample tube, and a cavity exists between the drive tube and the sample tube and between the drive tube and the end plugs; fixing components are further included, and a top portion port and a bottom portion port of the drive tube are each covered by the fixing component; after an explosive is detonated at the top portion, a detonation wave is transferred sequentially from top to bottom, and under impacting action, the drive tube performs convergent sliding motion towards an axis of the sample tube from top to bottom, so that the drive tube is sequentially wrapped from top to bottom around a top end plug of the sample tube, the sample tube, and a bottom end plug of the sample tube.

Taking the detonation impact synthesis of diamond as an example, the detonation impact synthesis of diamond is to introduce a strong shock wave into a mixture of graphite and copper powder, and a transient effect of thousands of degrees of temperature and hundreds of thousands of atmospheres is generated by the strong shock wave, to convert the graphite into the diamond; this transient violent process is completed within tens of μs to hundreds of μs, thus the dynamic high-pressure synthetic process itself is quite difficult to regulate and control, and the sealing end plugs at the end portions of the sample tube are easily blasted away, causing the sample to fly off, then the conversion rate is low, and the recovery is extremely difficult.

The double-tube connection structure of the sample tube and the drive tube designed in the present disclosure enables the end portion of the drive tube to perform convergent motion (poly heart movement) and plastic deformation, and further tightly wrap the end plug, can effectively prevent the sealing end plugs at the end portions of the sample tube from being blasted away, and facilitates improving the conversion rate and recovery rate.

Therefore, the drive tube in the present disclosure mainly can achieve the following two functions, one is acting as a carrier for absorbing explosive energy, wherein when the drive tube impacts the sample tube, the energy is transferred to the sample to generate a high-temperature, high-pressure condition for converting graphite into diamond, and the other is that after explosion, when the drive tube collides in cavity flight with the end plug and the sample tube at a high speed, the collision pressure of the drive tube with the end plug and the sample tube is far higher than the Hugoniot elastic limit of the material of the drive tube itself, the material enters a plastic zone, and undergoes a convergent effect (poly heart effect) and plastic deformation, so that the drive tube is tightly wrapped around the sample tube and sealing end plugs at two ends, preventing the end plugs from being blasted away, and enabling the raw material sample to be completely sealed in the sample tube; and the drive tube, the sample tube, and the sealing end plugs at two ends constitute a composite tube with very high strength by means of a strengthening effect of detonation, to form a complete recovery container of diamond sample, which can well seal the sample obtained when reaching a pressure of more than 20 GPa and a high temperature of several thousand degrees after impact loading.

Further, along the entire axial position of the sample tube, a circumferential equidistant gap between an inner wall of the drive tube and an outer wall of the sample tube serves as a cavity. In the present disclosure, no obstacle is designed between the drive tube and the sample tube, which is beneficial to ensure the uniform propagation of the detonation wave, so as to form high-temperature high-pressure synthesis condition, and the drive tube is allowed to perform convergent motion and plastic deformation to be tightly wrapped around the sample tube and the end plugs to form a composite tube with two ends closed.

Further, an outer diameter of a part of the end plug for being in wrapping contact with the drive tube is smaller than an outer diameter of the sample tube.

As a preferred solution, it is designed in such a manner that an outer diameter of a part of the end plug for being in wrapping contact with the drive tube is smaller than an outer diameter of the sample tube. In this way, when the high-pressure detonation product pushes the drive tube to perform convergent motion towards the axis of the end plug, a caliber of the drive tube after the shrinkage at the small diameter part of the end plug is smaller than that after the shrinkage at the sample tube, therefore, the drive tube automatically forms an end portion constriction structure, further improving the tightening effect on the end plug.

Further, the end plug is in a tapered structure, and a large diameter end of the tapered structure is connected to the sample tube.

Designing the end plug in a tapered structure facilitates stable downward transmission of the detonation wave while improving the fastening effect of the drive tube to the end plug.

Further, after detonation, when the detonation wave is transferred to a joint between an end portion of the drive tube and the fixing component, the joint between the end portion of the drive tube and the fixing component is disconnected, and the fixing component flies outwards under the action of tensioning wave (tensile wave).

From detonation physics, it can be known that in the air, when a cylindrical charge is detonated from an end plane, a ratio of mass (M1) and energy (E1) propagating in a detonation wave motion direction to mass (M2) and energy (E2) propagating in a direction opposite to the detonation wave motion direction is: M1/M2=4/5, E1/E2=16/11. At the end portions of the device, namely a top end and a bottom end of the sample tube, when the high-pressure detonation product is expanded in a divergent manner in the air, the tensioning wave will be generated, and when the tensioning wave is at the end portion of the sample tube and has enough strength, the orifice of the sample tube at the end portion may be broken, so that the sample in the tube is sprayed/jetted and leaked. In order to avoid the tensioning area (stretch zone) at the end portion, the fixing component is set at each of the end portions of the sample tube and the drive tube. The fixing component, after gaining momentum, flies outward and takes away the momentum, so that the end portion of the sample tube avoids the tensioning area, effectively preventing the orifice of the recovery container at the end portion from breaking, and achieving the purpose of completely recovering the sample.

Further, for the fixing component mounted at the top portion of the drive tube, it includes a fixing ring and at least one layer of cover plate; the fixing ring has one end connected to the top portion of the drive tube and the other end connected to the cover plate, the cover plate is configured to seal the cavity; the fixing component mounted at the bottom portion of the drive tube includes a fixing ring and a base, and the fixing ring has one end connected to the bottom portion of the drive tube and the other end connected to the base, and the base plays a fixing and supporting role.

The cover plate in the present disclosure is configured to fix the sample tube, the drive tube and the fixing ring, and seal a top opening of the cavity between the sample tube and the drive tube, so as to prevent the explosive from entering the cavity. The base is configured to fix and support the drive tube and the sample tube.

Further, the end portion of the drive tube and the end portion of the fixing ring are spliced with each other to form a coaxial barrel structure.

In the present disclosure, the drive tube and the fixing ring are connected by a splicing structure, which not only can ensure that the fixing ring can smoothly fly out and take away the momentum during the detonation process, but also can simplify the structure to the maximum extent and reduce the cost.

Further, a limiting ring I extending outwards in an axial direction is provided on an end surface of the bottom portion or the top portion of the drive tube, a limiting ring II extending outwards in an axial direction is provided on an end surface of corresponding fixing ring, and connection between the drive tube and the fixing ring is realized through the limiting ring I and the limiting ring II with one sleeved over the other.

On one hand, the connection structure between the drive tube and the fixing ring is greatly simplified, which is beneficial to reduce the manufacturing cost and the cost of loading and unloading; on the other hand, when the high-pressure detonation product pushes the end portion of the drive tube to make a convergent motion, the joint between the fixing ring and the drive tube will not produce any resistance.

Further, the fixing component further includes a fixing block, the fixing block is provided in the fixing ring, and the fixing block has one end connected to the end plug, and the other end connected to the cover plate or the base.

The fixing block and the fixing ring are added to the end portions of the sample tube and the drive tube. After these blocks and rings gain momentum, they fly outward and take away the momentum, which can effectively protect the end portions of the recovery container, and facilitate the complete recovery of the sample. In order to protect the end portion of the sample tube and take away as much momentum as possible, the weight of the fixing ring and the fixing block can be increased, for example, a metal ring or metal block structure is adopted.

The present disclosure also discloses a detonation synthesis device, which includes a housing, and also includes the above double-tube connection structure for detonation synthesis disposed in the housing, wherein a chamber between an inner wall of the housing and an outer wall of the drive tube is filled with a main explosive, bottom ends of the drive tube and the sample tube are mounted on a tray through the fixing component, and the tray is configured to seal a bottom end of the housing, and a top end of the housing is provided with a detonation component.

The present disclosure substantially provides a cylindrical surface sliding detonation double-tube impact synthesis device. After detonation at the top end of the device, a detonation wave is formed, the detonation wave propagates from top to bottom along the outer wall of the drive tube at a steady speed, and a high-pressure detonation product behind a detonation wave front pushes the drive tube to perform convergent sliding motion towards the axis of the device. During cavity flight, on an explosive-drive tube interface, due to the interaction between the compressional wave and rarefaction wave, the drive tube will continuously obtain energy from the explosive to continuously accelerate. Due to the convergent effect, the more the drive tube converges towards the axis, the higher its free-surface velocity will be. After the drive tube collides with the sample tube at a high speed, a stable detonation shock wave system is formed in the sample, and traverses the whole sample from top to bottom, so that the sample is uniformly compressed. Thus, the conversion rate of the present disclosure is quite high, reaching 90% or more, and the sample can be recovered by 100%.

Further, the detonation component includes a primer, a detonator fixing plate, and a detonator, wherein the primer is laid flat on a top layer of the main explosive, the primer is provided thereon with the detonator fixing plate, and the detonator fixing plate is fixed thereon with the detonator.

The above double-tube connection structure for detonation synthesis or the above detonation synthesis device can be used to convert low pressure phase materials into high pressure phase materials or to pulverize hard materials, wherein the high pressure phase materials include diamonds, carbides, nitrides, borides.

The present disclosure further provides a high-strength composite tube, wherein the high-strength composite tube is made after detonation of the above double-tube connection structure for detonation synthesis or the above detonation synthesis device.

The present disclosure further provides a high-strength pressure vessel, wherein the high-strength pressure vessel is made after detonation of the above double-tube connection structure for detonation synthesis or the above detonation synthesis device.

The present disclosure further provides a preparation method of the above high-strength composite tube and/or high-strength pressure vessel, wherein the high-strength composite tube and/or the high-strength pressure vessel is made after detonation of the above double-tube connection structure for detonation synthesis or the above detonation synthesis device.

The high pressure, high temperature, and high strain rate generated by the explosion and impact action form a unique comprehensive means of acting on substances. It has a wide application prospect. Besides being used for synthesizing diamond, the above device can also be widely applied to develop other new materials, for example, it can be used for synthesizing wurtzite type and sphalerite type boron nitride with hardness second to that of diamond, and can also be used for synthesizing ceramics with carbide, boride, and nitride structure such as TiC, TiB2, B4C, and SiC, which are light-weight and high-temperature resistant structural ceramics urgently required by many high-technology departments. In addition, it also can be used to pulverize super-hard materials, such as diamond, which are difficult to pulverize under normal circumstances, making them suitable for various different uses.

The present disclosure has the following advantages and beneficial effects.

1. The sample tube and drive tube connection structure provided in the present disclosure enables the end portions of the drive tube to perform convergent motion and plastic deformation, and further tightly wrap the end plugs, can effectively prevent the sealing end plugs at the end portions of the sample tube from being blasted away, and facilitates improving the conversion rate and recovery rate. Therefore, the drive tube in the present disclosure mainly can realize the following two functions, one is acting as a carrier for absorbing explosive energy, wherein when the drive tube impacts the sample tube, the energy is transferred to the sample to generate a high-temperature high-pressure condition for converting graphite into diamond, and the other is that after explosion, when the drive tube collides with the end plugs and the sample tube at a high speed in cavity flight, the collision pressures of the drive tube with the end plugs and the sample tube are far higher than the Hugoniot elastic limit of the material of the drive tube itself, the material enters a plastic zone, and undergoes a convergent effect and plastic deformation, so that the drive tube is tightly wrapped around the sample tube and sealing end plugs at two ends, preventing the end plugs from being blasted away, and enabling the raw material sample to be completely sealed in the sample tube to promote the complete reaction of the raw material sample; and the drive tube, the sample tube, and the sealing end plugs at two ends constitute a composite tube with very high strength by means of a strengthening effect of detonation, to form a recovery container of diamond sample, which can well seal the sample obtained when reaching a pressure of more than 20 GPa and a high temperature of several thousand degrees after impact loading.

2. The configuration of the present disclosure facilitates taking away the momentum, prevents the end portions of the sample tube from breaking. At the end portion of the device, when the high-pressure detonation product is expanded in a divergent manner in the air, the tensioning wave will be generated, and when the tensioning wave is at the end portion of the sample tube and has enough strength, the orifice of the sample tube at the end portion may be broken, so that the sample in the tube is sprayed and leaked. In order to avoid the tensioning areas at the end portions, the fixing rings and the fixing blocks are provided at the top ends and/or the bottom ends of the sample tube and the drive tube. The fixing rings and the fixing blocks, after gaining momentum, fly outward and take away the momentum, so that the end portions of the sample tube avoids the tensioning area, effectively preventing the end portions of the recovery container from breaking, and achieving the purpose of completely recovering the sample.

3. The fixing ring and the fixing block provided in the present disclosure facilitate stable transmission of the detonation waves moving to the sample tube. As there is a detonation distance from unstable to stable when the explosive is just detonated, adding the fixing block and the fixing ring of appropriate height on the top also can play a role in keeping away from the unstable detonation area of the explosive.

To synthesize diamond by the detonation impact, a strong shock wave is introduced into the mixture of the graphite and the copper powder, and the transient effect of thousands of degrees of temperature and hundreds of thousands of atmospheres is generated by the strong shock wave, to convert the graphite into the diamond; and the copper powder is used as a quenching agent, to enable the diamond phase, which is stable at a high temperature and a high pressure, to be preserved at a low temperature and a low pressure. The present disclosure makes this transient violent process controllable and adjustable and manageable according to people's requirements.

The present disclosure has important significance for breaking technical blockade and realizing industrial production of the polycrystalline diamond. The explosion synthesis or shock wave synthesis of new materials has become a new important technology in material researches, and this new technology has wide application prospect. Through years of detonation shock wave physical researches, and with profound theoretical knowledge and rich experimental skills, the inventors have mastered the internal rule of the phase conversion mechanism from graphite to diamond caused by impact, and skillfully designed and invented the device, which can meet the high-temperature high-pressure condition for converting graphite into diamond, so that the sample graphite is uniformly compressed and converted into high-purity polycrystalline diamond in the device. The conversion rate is unprecedentedly improved to 90% or more; and the converted product, high-purity polycrystalline diamond, is completely recovered. The device provided in the present disclosure can recover diamond by 100%, and can realize industrialized production.

### BRIEF DESCRIPTION OF DRAWINGS

Accompanying drawings described herein, constituting a portion of the present disclosure, are used to provide further understanding to the embodiments of the present disclosure, and do not limit the embodiments of the present disclosure. In the accompanying drawings:

FIG. 1 is a pressure-temperature phase diagram of carbon;

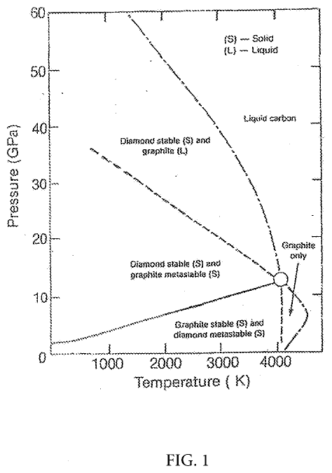

In FIG. 1, solid line: graphite-diamond phase equilibrium line; dot dash line: diamond melting line; dotted line: graphite melting line; and

FIG. 2 is a structural schematic diagram of a detonation synthesis device of the present disclosure.

### REFERENCE SIGNS IN THE ABOVE ACCOMPANYING DRAWINGS AND NAMES OF CORRESPONDING PARTS

1—sample, 2—sample tube, 3—cavity, 4—drive tube, 5—main explosive, 6—primer, 7—end plug, 8—fixing block, 9—fixing ring, 10—cover plate, 11—base, 12—wooden tray, 13—housing, 14—detonator positioning plate, 15—detonator.

### DETAILED DESCRIPTION OF EMBODIMENTS

In order to make objectives, technical solutions, and advantages of the present disclosure clearer, the present disclosure is further described in detail below in combination with embodiments and accompanying drawings. The exemplary embodiments of the present disclosure and description thereof are merely used to explain the present disclosure, rather than limiting the present disclosure.

### Embodiment 1

The present embodiment provides a double-tube connection structure for detonation synthesis, including a drive tube 4 and a sample tube 2, wherein the drive tube 4 and the sample tube 2 are both of circular tube structure, the drive tube 4 is coaxially sleeved outside the sample tube 2, and an annular gap (circumferential gap) between an inner wall of the drive tube 4 and an outer wall of the sample tube 2 serves as a cavity 3; a top port and a bottom port of the sample tube 2 are each provided with a sealing end plug 7, and the top port and the bottom port of the sample tube 2 are both located in the drive tube 4. Fixing components are further included, and a top portion port and a bottom portion port of the drive tube 4 are each covered by the fixing component, then a main explosive can be prevented from entering the cavity 3; after detonation, a detonation wave is transferred from top to bottom, and under the action of impact, the drive tube 4 performs convergent sliding motion towards an axis of the sample tube 2 from top to bottom, so that the drive tube 4 is sequentially wrapped from top to bottom around the top end plug 7 of the sample tube 2, the sample tube 2, and a bottom end plug 7 of the sample tube 2, forming a composite tube, where the composite tube is a complete recovery container.

### Embodiment 2

On the basis of Embodiment 1, it is further improved that an outer diameter of a part of the end plug 7 for being in wrapping contact with the drive tube 4 is smaller than an outer diameter of the sample tube 2; further preferably, the end plug 7 is of a circular truncated cone structure, a large diameter end of the circular truncated cone structure is inserted into a port of the sample tube 2, and a small diameter end of the circular truncated cone structure is connected to the fixing component.

### Embodiment 3

On the basis of Embodiment 1 or 2, it is further improved that for the fixing component, after detonation, when the detonation wave is transferred to a joint between an end portion of the drive tube 4 and the fixing component, the joint between the end portion of the drive tube 4 and the fixing component is disconnected (the end portion of the drive tube 4 is disconnected with and separated from the fixing component), then the fixing component flies outwards under the action of tensioning wave; the end portion of the drive tube 4, after performing convergent motion towards the axis of the sample tube 2, is wrapped around the end plug 7. As a preferable solution, the fixing component mounted at the top portion of the drive tube 4 includes a fixing ring 9 and two layers of cover plates 10; the fixing ring 9 has one end connected to the top portion of the drive tube 4, and the other end connected to the cover plates 10; the cover plates 10 are configured to seal the cavity 3, an annular groove is provided on a lower plate surface of the cover plate 10, and an end portion of the fixing ring 9 can be embedded into the annular groove and fixed. The fixing component mounted at the bottom portion of the drive tube 4 includes a fixing ring 9 and a base 11, and the fixing ring 9 has one end connected to the bottom portion of the drive tube 4, and the other end connected to the base 11; and the base 11 plays a supporting role.

The structure for realizing the connection between the drive tube 4 and the fixing ring 9 is as follows: the end portion of the drive tube 4 and the end portion of the fixing ring 9 are spliced with each other to form a coaxial barrel structure. Specifically, the connection structure between the top portion of the drive tube 4 and the fixing component is as follows: an inner side of an end surface of the drive tube 4 extends outwards in an axial direction and is provided with a limiting inner ring, an outer side of an end surface of the fixing ring 9 extends outwards in the axial direction and is provided with a limiting outer ring, the limiting outer ring is sleeved outside the limiting inner ring, an end surface of the limiting inner ring abuts against the end surface of the fixing ring 9, and the end surface of the limiting outer ring abuts against the end surface of the drive tube 4. The connection structure between the bottom portion of the drive tube 4 and the fixing component is as follows: an outer side of the end surface of the drive tube 4 extends outwards in the axial direction and is provided with a limiting outer ring, an inner side of an end surface of the fixing ring 9 extends outwards in the axial direction and is provided with a limiting inner ring, the limiting outer ring is sleeved outside the limiting inner ring, an end surface of the limiting inner ring abuts against the end surface of the drive tube 4, and the end surface of the limiting outer ring abuts against the end surface of the fixing ring 9.

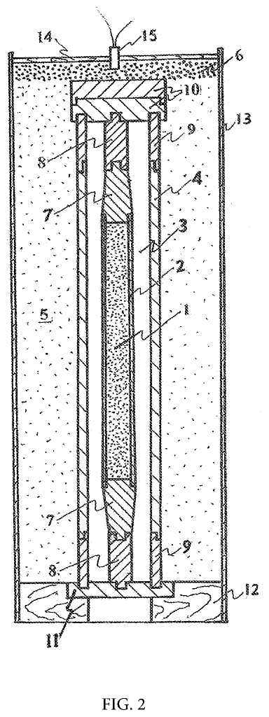

A further preferred solution further includes a fixing block 8, wherein the fixing block 8 is located inside the fixing ring 9, and the fixing block 8 has one end connected to the end plug 7, and the other end connected to the cover plate 10, as shown in FIG. 2; and the fixing block 8 and the fixing ring 9 are both made of a metal material.

### Embodiment 4

The present embodiment provides a detonation synthesis device, including a housing 13, the double-tube connection structure for detonation synthesis provided in Embodiment 3 mounted in the housing 13, wherein a chamber between an inner wall of the housing 13 and an outer wall of the drive tube 4 is filled with a main explosive. The fixing component provided at the top portions of the sample tube 2 and the drive tube 4 is composed of the fixing ring 9, the fixing block 8, and the cover plate 10, the fixing component provided at the bottom portions of the sample tube 2 and the drive tube 4 is composed of the fixing ring 9, the fixing block 8, and the base 11, and the base 11 is configured to fix the sample tube 2 and the drive tube 4, as well as the fixing block 8 and the fixing ring 9. The bottom portions of the drive tube 4 and the sample tube 2 are mounted on a wooden tray 12 through the fixing component, the wooden tray 12 is configured to seal a bottom end of the housing 13; and a top end of the housing 13 is provided with a detonation component.

### Embodiment 5

On the basis of Embodiment 4, it is further improved that the detonation component includes a primer 6, a detonator fixing plate 14, and a detonator 15, wherein the primer 6 is laid flat on a top layer of the main explosive 5, the primer layer has a bottom surface in contact with the top portion of the fixing component, and a top surface in contact with a lower plate surface of the detonator fixing plate 14; and the detonator fixing plate 14 is provided thereon with the detonator 15. The explosive is an energy source of the synthesis device. The amount of explosive of the device used in the present embodiment is 260 KG. The main explosive is placed in a gap between the housing 13 and the drive tube 4; a layer of RDX high power primer with a thickness of 1 cm-3 cm is laid on an entire top plane; and then the detonator 15 is inserted into the detonator positioning plate 14.

Polycrystalline diamond is synthesized using the device provided in Embodiment 5, and the synthesis principle is analyzed as follows.

1. A Certain High-Temperature High-Pressure Condition can be Created, so that Graphite is Converted into Diamond, and a High Conversion Rate is Obtained.

The present embodiment substantially provides a cylindrical surface sliding detonation double-tube impact synthesis device. After the explosive is detonated at the top end of the device, a detonation wave is formed in the explosive, the detonation wave propagates from top to bottom along the outer wall of the drive tube at a steady speed, and a high-pressure detonation product behind a detonation wave front pushes the drive tube to perform convergent motion towards the axis of the device. During cavity flight, on an explosive-drive tube interface, due to the interaction between the compressional wave and rarefaction wave, the drive tube will continuously obtain energy from the explosive to continuously accelerate. Due to the convergent effect, the more the drive tube converges towards the axis, the higher its free-surface velocity will be. After the drive tube and the sample tube collide with each other at a high speed, a shock wave forms a stable detonation impact system in the sample tube, and traverses the whole sample from top to bottom, so that the sample is uniformly compressed. Thus, the conversion rate of the present disclosure is quite high, reaching 90% or more.

2. Graphitization can be Prevented.

An impact compression process is accompanied by an unloading process of pressure. In the unloading process, in order to reduce the reverse phase change from diamond to graphite as much as possible, doping a metal powder (such as copper powder) with good thermal conductivity into the sample can achieve the effect of impact quenching, and this requirement can be met by selecting an appropriate mixing ratio of graphite to metal powder.

3. High Recovery Rate.

As the collision pressure between the drive tube and the sample tube is far higher than the Hugoniot elastic limit of the material of the drive tube itself, the material enters a plastic zone, and through the convergent effect and plastic deformation, the drive tube is tightly wrapped around the sample tube and sealing plugs at two ends, and the drive tube, the sample tube, and the sealing plugs at two ends constitute a composite tube with very high strength through the detonation action, becoming a recovery container for the diamond generated. Besides, at the end portion of the device, when the high-pressure detonation product expands in a divergent manner into the air, the tensioning wave will be generated, and when the tensioning wave is at the end portion of the sample tube and has sufficient strength, an orifice of the sample tube may be broken, and the sample in the tube may be jetted and leaked. To avoid a tensioning zone (stretch zone) at the end portion of the sample tube, the fixing block and the fixing ring are added at the end portions of the sample tube and the drive tube, in this way, the end portion of the recovery container can be effectively protected from being blasted away. The recovery rate of diamond can reach 100%.

After the diamond is synthesized by means of detonation impact, the sample (namely, mixture of diamond, graphite, and copper powder) is taken out from the recovery container of the composite tube, to undergo selective oxidation acid treatment, so as to separate out the diamond in the sample, and then subsequent purification operations such as screening and grading of the diamond are performed.

In conclusion, the detonation synthesis device provided in the present disclosure can meet the high-temperature high-pressure condition for converting graphite into diamond, so that the sample graphite is uniformly compressed and converted into high-purity polycrystalline diamond in the device. The conversion rate is unprecedentedly improved to 90% or more; and the converted product, high-purity polycrystalline diamond, is completely recovered, with the recovery rate reaching 100%.

The inventors have successfully synthesized high-purity nano-structured polycrystalline diamond through the device, the conversion rate reaches 90% or more, the converted product, high-purity nano-structured polycrystalline diamond, is fully recovered by 100%, with the particle size being normally distributed in 0-32 μm, and the industrialized production can be fully realized.

The above-mentioned embodiments have further illustrated the objectives, the technical solutions, and the beneficial effects of the present disclosure in detail. It should be understood that the above-mentioned are merely specific embodiments of the present disclosure, rather than limiting the scope of protection of the present disclosure, and any amendments, equivalent replacements, improvements and so on made within the spirit and principle of the present disclosure should be covered within the scope of protection of the present disclosure.

What is claimed is:

1. A double-tube connection structure for detonation synthesis, comprising a drive tube, a sample tube, fixing components, and end plugs provided at two ends of the sample tube, wherein the drive tube is sleeved outside the sample tube and a cavity exists both between the drive tube and the sample tube and between the drive tube and the end plugs, and the fixing components are provided at two ends of the drive tube and the sample tube and are configured to fix the drive tube and the sample tube,
wherein after detonation at a top portion, a detonation wave is transferred from top to bottom, and under an action of the detonation wave, the drive tube performs convergent sliding motion towards an axis of the sample tube from top to bottom, the fixing components are separated from the drive tube and the sample tube and fly outwards under an action of a tensioning wave, and the drive tube is sequentially wrapped from top to bottom around a top end plug of the sample tube, the sample tube, and a bottom end plug of the sample tube, to form a composite tube with two ends closed, becoming a complete recovery container.

2. The double-tube connection structure for detonation synthesis according to claim 1, wherein an annular gap between an inner wall of the drive tube and an outer wall of the sample tube serves as a cavity.

3. The double-tube connection structure for detonation synthesis according to claim 1, wherein an outer diameter of a part of each of the end plugs for being in wrapping contact with the drive tube is smaller than an outer diameter of the sample tube.

4. The double-tube connection structure for detonation synthesis according to claim 3, wherein the end plug is in a tapered structure, and a large diameter end of the tapered structure is connected to the sample tube.

5. The double-tube connection structure for detonation synthesis according to claim 1, wherein the fixing component provided at a top portion of the drive tube comprises a fixing ring and at least one layer of cover plate; the fixing ring has one end connected to the top portion of the drive tube and the other end connected to the cover plate, the cover plate is configured to seal the cavity; and the fixing component provided at a bottom portion of the drive tube comprises a fixing ring and a base, and the fixing ring has one end connected to the bottom portion of the drive tube and the other end connected to the base, and the base plays a fixing and supporting role.

6. The double-tube connection structure for detonation synthesis according to claim 5, wherein the top portion and/or bottom portion of the drive tube and an end portion of the fixing ring are spliced with each other to form a coaxial barrel structure.

7. The double-tube connection structure for detonation synthesis according to claim 6, wherein an end surface of the bottom portion and/or an end surface of the top portion of the drive tube is provided with a limiting ring I extending outwards in an axial direction, an end surface of the corresponding fixing ring is provided with a limiting ring II extending outwards in an axial direction, and connection between the drive tube and the fixing ring is realized through the limiting ring I and the limiting ring II with one sleeved over the other.

8. The double-tube connection structure for detonation synthesis according to claim 5, wherein the fixing component further comprises a fixing block, the fixing block is provided inside the fixing ring, and the fixing block has one end connected to the end plug and the other end connected to the cover plate or the base.

9. A detonation synthesis device, comprising a housing and the double-tube connection structure for detonation synthesis according to claim 1 provided in the housing, wherein a chamber between an inner wall of the housing and an outer wall of the drive tube is filled with a main explosive, bottom ends of the drive tube and the sample tube are mounted on a tray through the fixing component and the tray is configured to seal a bottom end of the housing, and a top end of the housing is provided with a detonation component.

10. The detonation synthesis device according to claim 9, wherein the detonation component comprises a primer, a detonator fixing plate, and a detonator, the primer is laid flat on a top layer of the main explosive, the primer is provided thereon with the detonator fixing plate, and the detonator fixing plate is fixed thereon with the detonator.

11. A method for using the detonation synthesis device according to claim 9, comprising using the detonation synthesis device to convert low pressure phase materials into high pressure phase materials or to pulverize hard materials, wherein the high pressure phase materials comprise diamonds, carbides, nitrides and borides,
wherein the double-tube connection structure for detonation synthesis is configured to convert low pressure phase materials into high pressure phase materials or to pulverize hard materials, wherein the high pressure phase materials comprise diamonds, carbides, nitrides and borides.

12. A preparation method of a high strength composite tube and/or a high strength pressure vessel, wherein the high strength composite tube and/or the high strength pressure vessel is made after detonation of a double-tube connection structure for detonation synthesis according to claim 1 or a detonation synthesis device,
wherein the detonation synthesis device comprises a housing and the double-tube connection structure for detonation synthesis provided in the housing, wherein a chamber between an inner wall of the housing and an outer wall of the drive tube is filled with a main explosive, bottom ends of the drive tube and the sample tube are mounted on a tray through the fixing component and the tray is configured to seal a bottom end of the housing, and a top end of the housing is provided with a detonation component.

13. The double-tube connection structure for detonation synthesis according to claim 2, wherein an outer diameter of a part of each of the end plugs for being in wrapping contact with the drive tube is smaller than an outer diameter of the sample tube.

14. The double-tube connection structure for detonation synthesis according to claim 6, wherein the fixing component further comprises a fixing block, the fixing block is provided inside the fixing ring, and the fixing block has one end connected to the end plug and the other end connected to the cover plate or the base.

15. The double-tube connection structure for detonation synthesis according to claim 7, wherein the fixing component further comprises a fixing block, the fixing block is provided inside the fixing ring, and the fixing block has one end connected to the end plug and the other end connected to the cover plate or the base.

16. The detonation synthesis device according to claim 9, wherein an annular gap between an inner wall of the drive tube and an outer wall of the sample tube serves as a cavity.

17. The detonation synthesis device according to claim 9, wherein an outer diameter of a part of each of the end plugs for being in wrapping contact with the drive tube is smaller than an outer diameter of the sample tube.

18. The detonation synthesis device according to claim 17, wherein the end plug is in a tapered structure, and a large diameter end of the tapered structure is connected to the sample tube.

19. The detonation synthesis device according to claim 9, wherein the fixing component provided at a top portion of the drive tube comprises a fixing ring and at least one layer of cover plate; the fixing ring has one end connected to the top portion of the drive tube and the other end connected to the cover plate, the cover plate is configured to seal the cavity; and the fixing component provided at a bottom portion of the drive tube comprises a fixing ring and a base, and the fixing ring has one end connected to the bottom portion of the drive tube and the other end connected to the base, and the base plays a fixing and supporting role.

20. The detonation synthesis device according to claim 19, wherein the top portion and/or bottom portion of the drive tube and an end portion of the fixing ring are spliced with each other to form a coaxial barrel structure.
